(19) United States
(12) Patent Application Publication
(10) Pub. No.: US 2002/0185586 A1
(43) Pub. Date: Dec. 12, 2002

(54) System and mehod for optimizing the focusing capability of electromagnetic sensors

(76) Inventors: Robert E. Majewski, Tucson, AZ (US); Kathryn Wald, Tucson, AZ (US)

Correspondence Address: Patent Docket Administraion, RAYTHEON COMPANY, Bldg. EP/EO1/E151, P.O. Box 902, Los Angeles, CA, 90245-0902, US

(21) Appl. No.: 10/114,549

(22) Filed: Apr. 2, 2002

Related U.S. Application Data
(60) Provisional application No. 60/281,200, filed on Apr. 3, 2001.

(51) Int. Cl. H01L 27/00

(52) U.S. Cl. 250/208.1

(57) ABSTRACT

A system for tuning an imaging sensor adapted for use with an electromagnetic imaging sensor having a focal plane array of detectors. The inventive system includes a target slide for providing a simulated far field target. A translation stage adjusts the position of the target slide relative to the imaging sensor. The sensor has a focal plane and a lens disposed between the array and the target slide. A computer connected to the imaging sensor measures an output of the focal plane array at each of a plurality of positions of the target slide. The computer provides a signal representative of an optimal distance between the lens and the array in response to the output of the focal plane array of the sensor. In the illustrative embodiment, an electromagnetic energy source, a collimator, and a slit target slide provide a first strip of collimated electromagnetic energy. A sensor lens directs the first strip of electromagnetic energy upon the focal plane array so that the first strip impinges diagonally across a plurality of detectors. An image capturing device captures image information corresponding to the first strip and subsequently adjusts the position of the slit target slide to provide a second strip of electromagnetic energy. The computer is connected to the image capturing device and determines distance that the focal plane array must be moved relative to the sensor lens to optimize the sensor's ability to focus objects in response to the captured image information corresponding to the first strip and the second strip.

### CROSS-REFERENCE TO RELATED APPLICATIONS

This application claims benefit of U.S. Provisional Application Serial No. 60/281,200, filed Apr. 3, 2001.

### BACKGROUND OF THE INVENTION

1. Field of Invention

This invention relates to sensors used for imaging electromagnetic energy. Specifically, the present invention relates systems for maximizing the focusing capability of sensors having arrays of electromagnetic energy detectors.

2. Description of the Related Art

Electromagnetic imaging sensors are used in a variety of applications ranging from infrared missile guidance to space telescope applications. Such applications require optically efficient, sensitive sensors with accurate focusing capabilities.

An optically efficient sensor is a sensor that converts a relatively large percentage of received light energy into electrical signals for processing. A sensor typically has a front lens that images electromagnetic energy onto a focal plane array of energy detectors in the sensor. Optical efficiency is related to the fraction of energy that a given detector in the focal plane array detects relative to the total energy received by the focal plane array from a given source. The total energy received per pixel for a given test source must often meet certain stringent requirements that vary for different applications.

When manufacturing the sensors, adjustments often need to be made to the sensors to maximize sensor efficiency. These adjustments typically include optimizing the sensor's ability to focus objects. To maximize the sensor's ability to focus objects, the distance between the sensor's focal plane array of detectors and its front lens must be properly adjusted. If this distance is not accurately determined and adjusted, the sensor will have reduced optical efficiency. Later in the manufacturing process, if the sensor fails to meet certain efficiency thresholds, the sensor will often be discarded and wasted.

To accurately adjust the distance between a sensor's focal plane array and its front lens a technique using point source centering was developed. In this technique, a beam of light having sub-pixel dimensions is centered on a detector in the focal plane array. The distance between the focal plane array and its front lens is then adjusted to coincide with a peak electrical response. If the beam is not exactly centered on the detector, the resulting distance determination will be erroneous and the sensor will have poor focusing capability. Temporal noise often significantly degrades the quality of the distance measurement. Also, the act of adjusting the focus will often cause the beam to no longer be centered on the detector. Using this method to accurately adjust a sensor's focus is a painstaking, iterative process.

Hence, a need exists in the art for automated system and method for determining the distance between the focal plane array of detectors and the front lens of an electromagnetic sensor required to optimize the focus of the sensor for a particular application. There is a further need for a system that minimizes distance measurement errors introduced via temporal noise.

### SUMMARY OF THE INVENTION

The need in the art is addressed by the system for tuning an imaging sensor of the present invention. In the illustrative embodiment, inventive system is adapted for use with an electromagnetic imaging sensor having a focal plane array of detectors. The system includes a target slide for providing a simulated far field target. A translation stage adjusts the position of the target slide relative to the imaging sensor. The sensor has a focal plane and a lens disposed between the array and the target slide. A computer connected to the imaging sensor measures an output of the focal plane array at each of a plurality of positions of the target slide. The computer provides a signal representative of an optimal distance between the lens and the array in response to the output of the focal plane array of the sensor.

In the illustrative embodiment, an electromagnetic energy source, a collimator, and a slit target slide provide a first strip of collimated electromagnetic energy. A sensor lens directs the first strip of electromagnetic energy upon the focal plane array of detectors so that the first strip impinges diagonally across a plurality of detectors. An image capturing device captures image information corresponding to the first strip and subsequently adjusts the position of the slit target slide to provide a second strip of electromagnetic energy. A computer connected to the image capturing device determines distance that the focal plane array must be moved relative to the sensor lens to optimize the sensor's ability to focus objects in response to captured image information corresponding to the first strip and the second strip. The above system is adaptable for use with a plurality of strips of electromagnetic energy corresponding to different positions of the slit target slide.

In a specific embodiment, the electromagnetic energy source is a blackbody illumination source. The slit target slide has a slit that is angled with respect to columns or rows of detectors in the focal plane array of detectors. A translation stage facilitates the movement of the angled slit target slide along an optical axis of the system. The device for capturing image information includes a computer that is connected to the sensor.

In the illustrative embodiment, software running on a computer curve fits image information corresponding to the first strip and the second strip to a parabola. The vertex of the parabola is determined via the software which is subsequently utilized to compute the distance between the focal plane array and the front lens required for optimum sensor focus.

The novel design of the present invention is facilitated by the curve fitting software which by fitting the image information to a parabola averages out distance measurement and calculation errors introduced via temporal noise.

### BRIEF DESCRIPTION OF THE DRAWINGS

FIG. 1 is a block diagram showing key functional blocks of a system for collecting focusing data constructed in accordance with the teachings of the present invention.

FIG. 2 is a more detailed diagram of the system of FIG. 1 illustrating key distances required for optimizing sensor focus for objects at infinity.

FIG. 3 is a diagram of the slit target slide of FIG. 1 showing the relative angle of the slit in the slit target slide with respect to the focal plane array of detectors.

FIG. 4 is a flow diagram illustrating key functional steps performed by the computer of FIG. 1.

### DESCRIPTION OF THE INVENTION

While the present invention is described herein with reference to illustrative embodiments for particular applications, it should be understood that the invention is not limited thereto. Those having ordinary skill in the art and access to the teachings provided herein will recognize additional modifications, applications, and embodiments within the scope thereof and additional fields in which the present invention would be of significant utility.

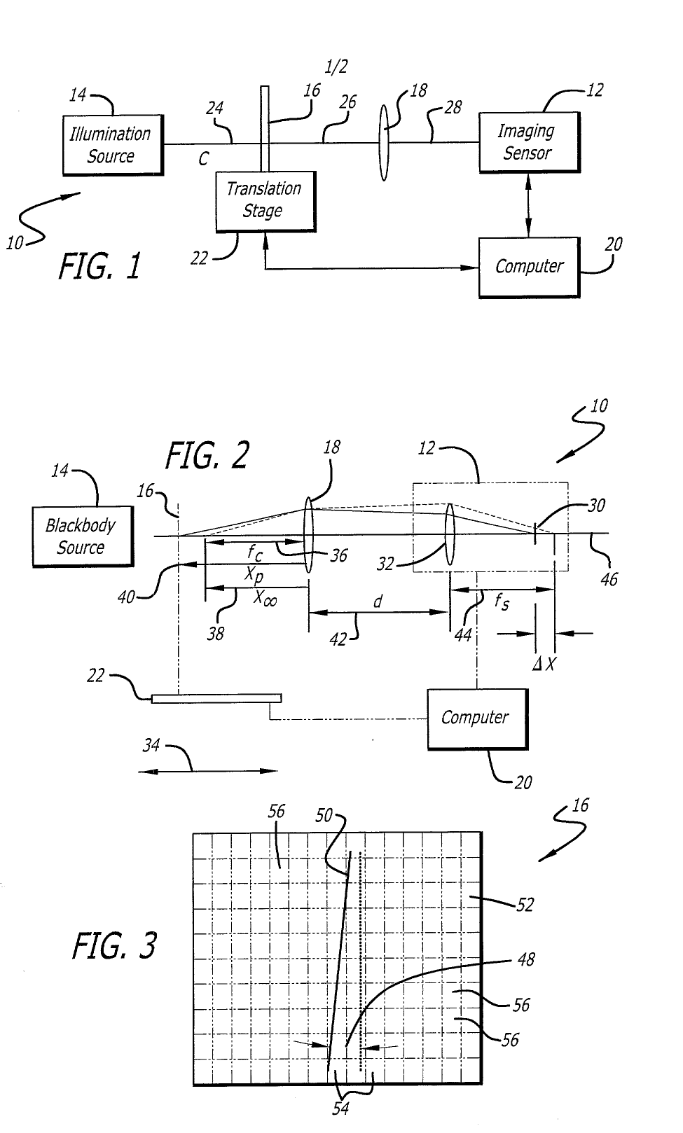

FIG. 1 is a block diagram showing key functional blocks of a system 10 for collecting focusing data constructed in accordance with the teachings of the present invention. The system 10 is used for determining the change in position of the focal plane array of an imaging sensor 12 with respect to its front lens (FIG. 2) required to optimize the sensor's 12 focusing capability for a particular application.

The system 10 includes an illumination source 14. A slit target slide 16 is disposed between a collimator 18 and the illumination source 14. The collimator 18 is positioned between the slit target slide 16 and the imaging sensor 12. A computer 20 connects the imaging sensor 12 and a translation stage 22.

The illumination source 14 radiates black body electromagnetic energy 24 toward the slit target slide 16. The electromagnetic energy 24 passes through an angled slit (see FIG. 3) in the slit target slide 16. Resulting electromagnetic energy 26 is then collimated by the collimator 18. Collimated electromagnetic energy 28 is then imaged by the sensor 12. The computer 20 stores the resulting image data collected by the sensor 12 for future processing. The computer 20 then issues a command to the translation stage 22 that steps the slit target slide 16 to a new predetermined position along the optical axis of the system 10. The sensor then images electromagnetic energy corresponding to the new slit target slide 16 position. Resulting image information is again stored by the computer 20. Those skilled in the art will appreciate that the back lit slit (see FIG. 3) in the target slide 16 acts as a simulated far field target.

The computer 20 collects several frames of image data corresponding to different slit target slide 16 positions. The number of slit target slide 16 positions for which the computer 20 stores image information is a function of the sensor focusing accuracy required for a given application. To more accurately determine the positional adjustment of the sensor's 12 focal plane array requires a smaller positional step size for the slit target slide 16.

After the computer 20 has collected image information corresponding to a predetermined set of slit target slide 16 positions, the computer 20 calculates the change in position required for the focal plane array of the sensor 12 with respect to its front lens (see FIG. 2) to maximize the ability of the sensor 12 to focus objects, and to maximize the sensor's 12 optical efficiency. The calculations involve finding the position of the slit target slide 16 that results in the brightest image, and using this position to calculate the required change in distance between the sensor's front lens, and the focal plane array 30.

As mentioned above, FIG. 2 is a more detailed diagram of the system of FIG. 1 illustrating key distances required for optimizing the sensor's 12 focus for an application requiring focusing for targets at infinity. The focus is optimized by selectively adjusting the distance between a focal plane array (FPA) 30 and a front lens 32 of the sensor 12 in response to calculations performed by the computer 20 on image data gathered for different positions of the slit target slide 16.

In the present specific embodiment, the slit target slide 16 steps through a series of positions within the range 34 via the translation stage 22 in response to movement commands received by the translation stage 22 from the computer 20. The step size corresponding to the distance between positions is decreased for more accurate focus adjustments. The range 34 is approximately centered at the focal length (f_{c}) 36 of the collimator 18. The focal length f_{c}, corresponds to the infinity position (X_{∞}) 38 of the slit target slide 16. The collimator 18 is a distance (d) 42 from the front lens 32, which has a focal length (fₛ) 44.

The slit target slide 16 is shown at a peak response position 40 corresponding to a distance Xₚ from the center of the collimator 18. At the peak position 40, electromagnetic energy received by the FPA 30 from the illumination source 14 is at a maximum. Xₚ must be accurately determined for optimizing the sensor's 12 focus.

In the present embodiment, the illumination source 14 is a black body source and is set to a temperature of approximately 470 degrees Kelvin. The width of the slit (see 50 of FIG. 3) of the slit target slide 16 is approximately one fifth of the collimator magnified width of an individual detector in the FPA 30. The slit shouldn't be so thin as to introduce large errors resulting from slit width nonuniformities or diffraction induced errors. The relative position of the slit target 16, the collimator 18, the sensor lens 32, and the FPA 30 are such that the entire slit of the slit target slide 16 may be imaged on the FPA 30. In the present specific embodiment, the image of the slit (not shown) overlies at least forty detectors in the FPA 30.

For each position of the slit target slide 16, the computer 20 locates the imaged line source (image of the slit target slide 16) in a frame of sensor data stored in the computer 20 and finds the peak value along each row of detectors that crosses the slit image (see FIG. 3). In the present embodiment, pixels that cross the slit image are defined to be those pixels having values within 35% of the peak pixel value in the entire frame of image data. The peak values in each row are then averaged to obtain an average peak value y(xᵢ) corresponding to the position xᵢ of the slit target slide 16, where i is a step index. y(xᵢ) approaches a parabola as xᵢ approaches x_{p.} The vertex of the parabola corresponds to the peak position 40 at the distance Xₚ from the center of the collimator 18.

To accurately approximate Xₚ all values y(xᵢ) that exceed a predetermined threshold are curve fit to a parabola. In the present specific embodiment, the predetermined threshold is 75% of the largest value of y(xᵢ). The curve fitting is performed by the computer 20. Techniques for curve fitting data points to functions such as a parabola are well known in the art and may be obtained from NUMERICAL RECIPES IN C, by Flannery, Press, Teukolosky, and Vetterling, published 1995 by Cambridge University Press.

The parabola takes on the functional form:

y(x)=a+bx+cx² (1)

where a, b, and c are constant coefficients which are determined in the curve fitting process.

The peak response position 40 is then

Xₚ=−b/(2c) (2)

which corresponds to the vertex of the parabola as defined by equation (1). The vertex is associated with the peak position 40.

The required adjustment Δx of the position of the focal plane array 30 along an optical axis 46 of the sensor lens 32 required to maximize the sensor's 12 focus is a function of the focal length fₛ of the sensor lens 32, the focal length f_{c} of the collimator 18, the infinity position X_{∞} of the translation stage 22 and the distance d between the collimator 18 and the sensor lens 32 as expressed in the following equation:

$$Δ x = {( \frac{{f}_{s}}{{f}_{c}} )}^{2} ( {x}_{p} - {x}_{∞} ) ( \frac{1}{1 + ( \frac{( {x}_{p} - {x}_{∞} )}{{f}_{c}} ) ( \frac{{f}_{c} + {f}_{s} + d )}{{f}_{c}} )} ) \qquad ( 3 )$$

In the present embodiment,

$$( \frac{1}{1 + ( \frac{( {x}_{p} - {x}_{∞} )}{{f}_{c}} ) ( \frac{{f}_{c} + {f}_{s} + d )}{{f}_{c}} )} ) \approx 1 \qquad ( 4 )$$

and the required adjustment Δx becomes:

Δx=(fₛ/f_{c})²(Xₚ−X_{∞}). (5)

When Δx is negative, shims are added, and the FPA 30 is moved closer to the sensor lens 32. When Δx is positive, shims are removed, and the FPA is moved further from the sensor lens 32.

The unique method of the present invention results in a reduction in measurement errors associated with temporal noise. By accumulating data points and fitting them to a parabola to facilitate the determination of the required distance adjustment Δx, the effect of temporal noise is averaged out. Errors resulting from temporal noise introduced at each data point (xᵢ, y(xᵢ)) tend to cancel the corresponding errors introduced at other data points as the number of data points increases.

FIG. 3 is a diagram of the slit target slide 16 of FIG. 1 showing a relative angle 48 of a slit 50 in the slit target slide 16 with respect to the FPA 52 (shown in phantom). The novel design of the present invention is facilitated by the fact that the slit 50 is angled with respect to vertical columns 54 of detectors 56 in the FPA 30.

In the present specific embodiment, the angle 48 is approximately 5 degrees. By tilting the slit 50, electromagnetic energy from the illumination source (see FIG. 2) impinges on several detectors in more than one column 54 in the FPA 52. By directing electromagnetic energy diagonally across several detectors or pixels, measurement inconsistencies due to the misalignment of the slit 50 with respect to the detector columns 54 are avoided. The tilt angle 48 of the slit 50 allows a large number of slit/detectors separations to be sampled along the length of the slit 50. Averaging the peak values obtained in this manner alleviates the need for precision alignment of the slit 50 relative to pixel locations.

Those skilled in the art will appreciate that measurements of the present invention may be taken with the slit 50 slightly tipped from the horizontal rather than tipped from the vertical, or both, without departing from the scope of the present invention.

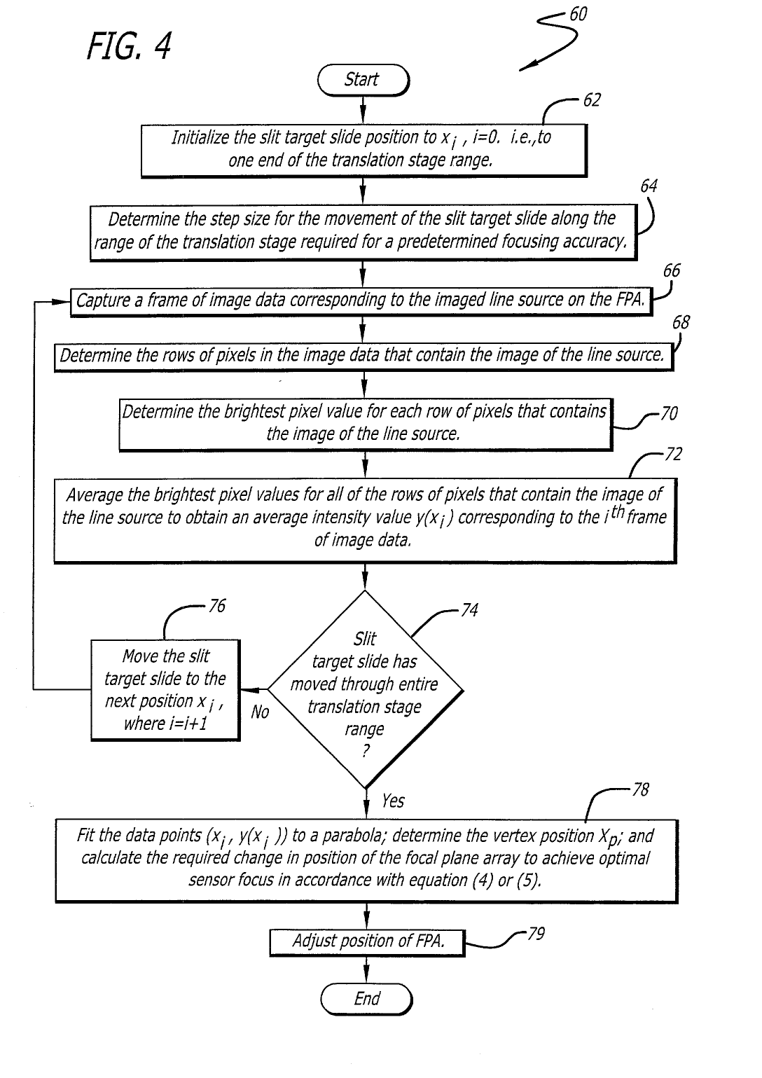

FIG. 4 is a flow diagram 60 illustrating key functional steps performed by the computer of FIG. 1. In an initialization step 62, the slit target slide (see 16 of FIG. 2) is moved to one end of the translation stage range (see 34 of FIG. 2). Subsequently, in a step size determination step 64, the step size of the movement of the slit target slide is determined. Smaller step sizes result in a more accurate measurement of Δx, i.e., the change in position of the FPA (see 30 of FIG. 2) required for optimum sensor focus. User input relating to a desired focusing accuracy is input into the computer in the step size determination step 64. In the present embodiment, the step size determination is determined experimentally and also input into the computer by the user in the step 64. Those skilled in the art will appreciate that software running on the computer may be used to determine the required step size (to achieve a predetermined accuracy) theoretically without departing from the scope of the present invention. Also, the steps 62, 64 may be swapped without departing from the scope of the present invention.

Next, in a frame capture step 66, the image on the FPA corresponding to the current position of the slit target slide is stored in the computer. Then, in an image determination step 68, the rows of pixels which contain the image of the line source in the frame of image data are determined.

The value of the brightest pixel in each row that contains the image data is then obtained and stored in a pixel step 70. These values are then averaged to obtain an average pixel intensity value y(x₁) for the given frame i at the position xᵢ in an averaging step 72. Currently, the position of the slit target slide is in the initial position and i=0.

Subsequently, a check is performed in a target slide position test step 74. In the step 74, the software running on the computer checks the position of the translation stage (see 22 of FIG. 2) to make sure that it has not completely traversed the translation stage range. If the slit target slide has not traversed the range, the slit target slide is moved to the next adjacent position (xᵢ₌ᵢ₊₁) in a slit target movement step 76. Control is then passed back to the frame capture step 66 where a new frame of image data corresponding to the new slit target slide position is captured and stored.

The steps 66, 68, 70, 72, 74, 76 form a loop which is exited when the slit target slide has moved across the entire translation stage range as checked in the position test step 74. The software has acquired a set of data points (xᵢ, y(xᵢ)) that are fit to a parabola in a position adjustment step 78. In the step 78, the vertex of the parabola is then determined and used to calculate the required positional adjustment of the FPA required to optimize the focus of the sensor (see 12 of FIG. 2). The position of the FPA is then adjusted.

Thus, the present invention has been described herein with reference to a particular embodiment for a particular application. Those having ordinary skill in the art and access to the present teachings will recognize additional modifications, applications and embodiments within the scope thereof.

It is therefore intended by the appended claims to cover any and all such applications, modifications and embodiments within the scope of the present invention.

Accordingly,

What is claimed is:

1. A system for tuning an imaging sensor comprising:
first means for providing a simulated far field target;
second means for adjusting the position of said target relative to an imaging sensor, said sensor having a focal plane and a lens disposed between said array and said target;
third means for measuring an output of said focal plane array at each of a plurality of positions of said target and providing an output in response thereto; and
fourth means for providing a signal representative of an optimal distance between said lens and said focal plane array in response to the output of said third means.

2. The invention of claim 1 wherein said first means includes means for directing a first beam of electromagnetic energy in a predetermined geometric configuration on detectors in said focal plane array.

3. The invention of claim 2 wherein said predetermined geometric configuration is a strip.

4. The invention of claim 3 wherein said electromagnetic energy is collimated.

5. The invention of claim 2 wherein said means for directing includes an illumination source.

6. The invention of claim 2 wherein said far field target includes an angled slit target slide having a slit that is angled with respect to columns or rows of detectors in said focal plane array of detectors.

7. The invention of claim 6 wherein said means for directing includes a translation stage for moving said angled slit target slide along an optical axis of said system.

8. The invention of claim 2 wherein said means for directing includes a collimator for collimating said beam of electromagnetic energy.

9. The invention of claim 2 wherein said third means includes means for capturing image information corresponding to said first beam and adjusting said second means in response to said captured image information for providing a second beam of electromagnetic energy.

10. The invention of claim 9 wherein the output of said third means includes captured image information corresponding to said first beam and said second beam.

11. The invention of claim 9 wherein said means for capturing image information includes a computer connected to said sensor.

12. The invention of claim 11 further including means for moving a translation stage with an angled slit target slide, said translation stage and said angled slit target slide included in said means for directing.

13. The invention of claim 12 wherein said fourth means includes software running on said computer for curve fitting image information corresponding to said first beam and said second beam to a parabola.

14. The invention of claim 13 including means for determining the vertex of said parabola.

15. The invention of claim 14 including means for utilizing said vertex to compute said optimal distance.

16. The invention of claim 15 wherein said means for utilizing said vertex includes software that executes the following equation:
Δx=(fₛ/f_{c})²(Xₚ−X_{∞})
where Δx is said optimal distance, Xₚ corresponds to the horizontal position of said vertex, X_{∞} corresponds to the infinity position of said slit target slide, fₛ is the focal length of said front lens, and f_{c} is the focal length of a collimator included in said means for directing.

17. The invention of claim 16 wherein said means for utilizing said vertex includes software that executes the following equation:
$$Δ x = {( \frac{{f}_{s}}{{f}_{c}} )}^{2} ( {x}_{p} - {x}_{∞} ) ( \frac{1}{1 + ( \frac{( {x}_{p} - {x}_{∞} )}{{f}_{c}} ) ( \frac{{f}_{c} + {f}_{s} - d )}{{f}_{c}} )} )$$
where Δx is said optimal distance, Xₚ corresponds to the horizontal position of said vertex, X_{∞} corresponds to the infinity position of said slit target slide, fₛ is the focal length of said front lens, and f_{c} is the focal length of a collimator included in said means for directing, and d corresponds to the distance between said front lens and said collimator.

18. A system for optimizing the focusing capability of an electromagnetic sensor having a focal plane array of detectors comprising:
means for directing a first beam of electromagnetic energy in a predetermined geometric configuration on a predetermined number of detectors in a focal plane array;
focusing means for directing said first beam of electromagnetic energy upon said focal plane array of detectors so that said first beam impinges diagonally across a plurality of detectors;
means for capturing image information corresponding to said first beam and adjusting said means for directing in response thereto for providing a second beam of electromagnetic energy;
means for providing a signal representative of an optimal distance between said focal plane array and said focusing means in response to said captured image information corresponding to said first beam and said second beam.

19. The invention of claim 18 wherein said predetermined geometric configuration is a strip.

20. The invention of claim 19 wherein said electromagnetic energy is collimated electromagnetic energy.

21. The invention of claim 18 wherein said means for directing includes an illumination source.

22. The invention of claim 21 wherein said illumination source is a blackbody source.

23. The invention of claim 21 wherein said means for directing further includes an angled slit target slide having a slit that is angled with respect to columns or rows of detectors in said focal plane array of detectors.

24. The invention of claim 23 wherein said means for directing includes a translation stage for moving said angled slit target slide along an optical axis of said system.

25. The invention of claim 21 wherein said means for directing includes a collimator.

26. The invention of claim 18 wherein said focusing means includes a front lens of said sensor.

27. The invention of claim 18 wherein said means for capturing image information includes a computer connected to said sensor.

28. The invention of claim 27 further including means for moving a translation stage with an angled slit target slide, said translation stage and said angled slit target slide included in said means for directing.

29. The invention of claim 27 wherein said means for providing includes software running on said computer for curve fitting image information corresponding to said first beam and said second beam to a parabola.

30. The invention of claim 29 including means for determining the vertex of said parabola.

31. The invention of claim 30 including means for utilizing said vertex to compute said distance.

32. The invention of claim 31 wherein said means for utilizing said vertex includes software that executes or approximates the following equation:
$$Δ x = ( \frac{{f}_{s}}{{f}_{c}} ) ( {x}_{p} - {x}_{∞} ) ( \frac{1}{1 + ( \frac{( {x}_{p} - {x}_{∞} )}{{f}_{c}} ) ( \frac{{f}_{c} + {f}_{s} - d )}{{f}_{c}} )} )$$
where Δx is said optimal distance, Xₚ corresponds to the horizontal position of said vertex, X_{∞} corresponds to the infinity position of said slit target slide, fₛ is the focal length of said lens, and f_{c} is the focal length of a collimator included in said means for directing, and d is the distance between the center of said lens and the center of said collimator.

33. A system for determining a change in distance between a focal plane array of detectors and a front lens of an electromagnetic energy sensor required to optimize the focus of the sensor comprising:
radiation means for providing a beam of electromagnetic energy;
angled slit means for providing a diagonal beam from said beam of electromagnetic energy.
lens means for focusing said diagonal beam into said sensor so that said diagonal beam forms an angle with respect to columns or rows of detectors in said focal plane array of detectors;
data collection means for selectively moving said angled slit means by a predetermined amount across a predetermined range and capturing a frame of image data from said sensor corresponding to the position of said angled slit means a predetermined number of times;
calculation means for obtaining an average intensity value for each of said predetermined number of frames of image data and fitting said average intensity values to a mathematical function representative of theoretically expected results and for determining the position of said angled slit means corresponding to a vertex of said mathematical function; and
means for utilizing said position to determine a change in position said focal plane array of detectors with respect to said front lens required to maximize the ability of said sensor to focus objects.
